(19) United States
(12) Patent Application Publication
(10) Pub. No.: US 2023/0216018 A1
(43) Pub. Date: Jul. 6, 2023

(54) METHOD AND SYSTEM FOR MANUFACTURING ELECTRODE

(71) Applicants: HYUNDAI MOTOR COMPANY, Seoul (KR); KIA CORPORATION, Seoul (KR)

(72) Inventor: Daewon Lee, Suwon-si (KR)

(21) Appl. No.: 17/947,498

(22) Filed: Sep. 19, 2022

(30) Foreign Application Priority Data
Dec. 31, 2021 (KR) 10-2021-0193820

(51) Int. Cl. H01M 4/04; H01M 50/533

(52) U.S. Cl. CPC H01M 4/0404; H01M 4/0409; H01M 50/533

(57) ABSTRACT

A method of manufacturing an electrode, the electrode including a coated portion coated with an electrode active material and an electrode tab protruding from the coated portion, the method including setting a region of the non-coated portion at a center of foil based on a longitudinal direction of the foil so that the region of the non-coated portion corresponds to a protruding length of the electrode tab, forming a pair of coated portions at two opposite sides of the non-coated portion by applying the electrode active material so that the pair of coated portions is symmetrically disposed at the two opposite sides based on the non-coated portion, and forming an electrode tab with a preset pattern by processing the non-coated portion by using a cutting unit.

### CROSS REFERENCE TO RELATED APPLICATIONS

This application claims priority to and the benefit of Korean Patent Application No. 10-2021-0193820 filed in the Korean Intellectual Property Office on Dec. 31, 2021, the entire contents of which are incorporated herein by reference.

### BACKGROUND

### (a) Field

The present disclosure relates to a method and system for manufacturing an electrode, and more particularly, to a method and system for manufacturing an electrode, which are capable of reducing the number of processes and costs.

### (b) Description of the Related Art

In general, a secondary battery refers to a battery capable of being charged and discharged unlike a primary battery that cannot be recharged.

Such secondary batteries are widely used for cutting-edge electronic devices such as mobile phones, notebook computers, computers, and camcorders.

The secondary batteries are classified into a can-type secondary battery in which an electrode assembly is embedded in a metal can and a pouch-type secondary battery in which an electrode assembly is embedded in a pouch.

The pouch-type secondary battery includes an electrode assembly, an electrolyte, and a pouch that accommodates the electrode assembly and the electrolyte.

Further, the electrode assembly has a structure in which negative electrodes and positive electrodes are alternately stacked with separators interposed therebetween.

Meanwhile, the negative or positive electrode is manufactured by coating one surface or two surfaces of copper or aluminum foil with a negative or positive electrode active material thin.

A raw material for the coating electrode has a coated portion and a non-coated portion which are distinguished depending on whether the negative or positive electrode active material is applied. In the following process, the non-coated portion is processed as a terminal serving as a passageway for electricity in the battery and makes a pair with the coated portion.

The process of coating the electrode is generally performed by supplying a raw foil material in the form of a continuous roll, applying and drying a negative or positive electrode active material, and then cutting the raw material into a shape and size intended to be obtained, thereby manufacturing sheets of negative and positive electrodes.

The raw material for an electrode may be designed by disposing one or more rows of plurality of coated portions by applying multiples of a dimension of the product in order to improve productivity.

An electrode coating process, which is performed continuously in a direction (progress direction) in which the raw foil material in the form of a roll is unwound, is referred to as a continuous coating process. Further, an electrode coating process, which is performed intermittently and repeatedly in a direction normal to the direction in which the raw foil material is unwound, is referred to as a pattern coating process.

The raw material for an electrode, which is manufactured through the continuous or repeated coating process, is generally wound again in the form of a roll.

Further, a typical process of manufacturing a secondary battery by stacking sheets of electrodes generally manufactures a raw material for an electrode by the continuous coating process.

The raw material for an electrode manufactured as described above may be applied to a rolling process in order to improve bondability of the applied electrode active material and ensure uniformity of quality of the battery by uniformizing thicknesses thereof.

Next, a slitting process may be applied in which a cutting device is used to cut the raw material for an electrode into a width or length of the sheet of electrode and cut out an unnecessary portion in the direction (progress direction) in which the electrode raw material is unwound.

The slitting process may have a plurality of blades or the plurality of blades may be eliminated depending on the number of rows on the raw material for an electrode on which the electrode coating process is performed.

It is possible to obtain one or more electrode rolls each having a pair of non-coated and coated portions through the slitting process.

Next, it is possible to apply a notching process of processing the non-coated portion of the corresponding raw material in a predetermined shape through a method such as mold shearing or laser cutting.

A shape of the non-coated portion processed by the notching process becomes a terminal serving as a passageway for each of the sheets of electrodes at the time of configuring the secondary battery.

The electrode inputted to the notching process may be processed to respective sheets of electrodes by processing the shape of the terminal by the notching process and additionally processing the sheets of continuously inputted electrodes or performing an additional subsequent process.

The negative and positive electrodes manufactured as described above are sequentially stacked with the separator interposed therebetween, thereby completely constituting the electrode assembly.

In general, the slitting process and the notching process are separately performed. However, in some instances, the slitting process and the notching process are integrated depending on the type of processing method.

The integrated slitting/notching process is typically implemented through laser cutting.

That is, the integrated slitting/notching process typically processes a shape of one row of the electrode terminal on one row of the non-coated portion of one row of the electrode by laser cutting.

However, because a method of manufacturing an electrode in the related art has a structure that needs to form a non-coated portion for each coated portion, there is a problem in that an area of the non-coated portion to be needed is large.

In addition, according to the method of manufacturing an electrode in the related art, processing devices need to be provided for each of the non-coated portions, which makes it difficult to ensure stability of the processes. For this reason, there is a likelihood that investment costs for facility are large, a large number of raw materials are consumed, and the non-coated portion is damaged during the processing.

Further, according to the method of manufacturing an electrode in the related art, a large number of scraps are discarded during a process of processing an electrode tab in a notching process, which degrades process stability.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a method and system for manufacturing an electrode, which may use a non-coated portion formed between a pair of coated portions, thereby minimizing a region of the non-coated portion and reducing costs.

An exemplary embodiment of the present disclosure provides a method of manufacturing an electrode, which manufactures an electrode including a coated portion coated with an electrode active material, and an electrode tab protruding from the coated portion, the method including a first step of setting a region of the non-coated portion at a center of foil based on a longitudinal direction of the foil so that the region of the non-coated portion corresponds to a protruding length of the electrode tab, a second step of forming a pair of coated portions at two opposite sides of the non-coated portion by applying the electrode active material so that the pair of coated portions is symmetrically disposed at the two opposite sides based on the non-coated portion, and a third step of forming an electrode tab with a preset pattern by processing the non-coated portion by using a cutting unit.

In addition, the second step may be a step of coating the foil with any one of the positive electrode active material and the negative electrode active material.

In addition, the second step may further include drying the foil after the foil is coated with the positive electrode active material or the negative electrode active material.

In addition, the method may further include, after the second step, rolling the foil by using rolling rollers.

In addition, the third step may be a step of processing the electrode tab by patterning the non-coated portion while the cutting unit regularly moves along the boundaries between the pair of coated portions and the non-coated portion.

In addition, the third step may be a step of patterning the non-coated portion by emitting a laser beam.

In addition, the method may further include, after the third step, a fourth step of forming a negative electrode or a positive electrode by cutting the pair of coated portions into pieces each having a predetermined size and including the single electrode tab.

Another exemplary embodiment of the present disclosure provides a system for manufacturing an electrode, which manufactures an electrode including a coated portion coated with an electrode active material, and an electrode tab protruding from the coated portion, the system including a conveying unit configured to convey foil in one direction while unwinding the wound foil, a coating unit disposed above the conveying unit, provided at a front side based on a conveyance direction of the foil, and configured to form a pair of coated portions and a non-coated portion between the pair of coated portions by coating the foil with the electrode active material, and a cutting unit disposed rearward of the coating unit based on the conveyance direction of the foil and configured to process the electrode tab by patterning the non-coated portion.

In addition, the cutting unit may include a laser generator configured to emit a laser beam, an optical box configured to transmit the laser beam emitted from the laser generator, a scanner configured to irradiate the non-coated portion with the laser beam; a focal point lens configured to focus the laser beam scanned by the scanner onto the non-coated portion, and a controller configured to move the scanner to a preset pattern.

In addition, the cutting unit may be configured such that the scanner emits the laser beam while being regularly moved along boundaries between the pair of coated portions and the non-coated portion by the controller.

In addition, the cutting unit may further include a dust collecting part configured to collect dust produced at the time of patterning the non-coated portion by emitting the laser beam to the non-coated portion.

In addition, the cutting unit may further include a guide part configured to fix the foil to prevent a movement of the foil.

In addition, the guide part may be disposed below the focal point lens in a vertical direction, move together with the scanner, and have a through-hole through which the laser beam passes to reach the non-coated portion.

Since the method and system for manufacturing an electrode according to the embodiment of the present disclosure may use the non-coated portion formed between the pair of coated portions, thereby minimizing the region of the non-coated portion and reducing costs.

In addition, since the method and system for manufacturing an electrode according to the embodiment of the present disclosure may simultaneously perform the slitting and notching processes, thereby minimizing the number of processes and reducing facility costs.

Other effects, which may be obtained or expected by the embodiments of the present disclosure, will be directly or implicitly disclosed in the detailed description on the embodiments of the present disclosure. That is, various effects expected according to the embodiments of the present disclosure will be disclosed in the detailed description to be described below.

### BRIEF DESCRIPTION OF THE FIGURES

FIG. 1 is a configuration view of a secondary battery to which an electrode manufactured by a method and system for manufacturing an electrode according to the embodiment of the present disclosure is applied.

FIGS. 2, 3, 4, and 5 are process diagrams sequentially illustrating the method of manufacturing an electrode according to the embodiment of the present disclosure.

FIG. 6 is a configuration view illustrating the system for manufacturing an electrode according to the embodiment of the present disclosure.

### DETAILED DESCRIPTION

Hereinafter, embodiments of the present disclosure will be described in detail with reference to the accompanying drawings so that those with ordinary skill in the art to which the present disclosure pertains may easily carry out the embodiments. However, the present disclosure may be implemented in various different ways and is not limited to the embodiments described herein.

A part irrelevant to the description will be omitted to clearly describe the present disclosure, and the same or similar constituent elements will be designated by the same reference numerals throughout the specification.

The size and thickness of each component illustrated in the drawings are arbitrarily shown for ease of description, but the present disclosure is not necessarily limited thereto. In order to clearly describe several portions and regions, thicknesses thereof are enlarged.

Further, in the following detailed description, names of constituent elements are classified as a first . . . , a second . . . , and the like so as to discriminate the constituent elements having the same name, and the names are not essentially limited to the order in the description below.

Throughout the specification, unless explicitly described to the contrary, the word “comprise/include” and variations such as “comprises/includes” or “comprising/including” will be understood to imply the inclusion of stated elements, not the exclusion of any other elements.

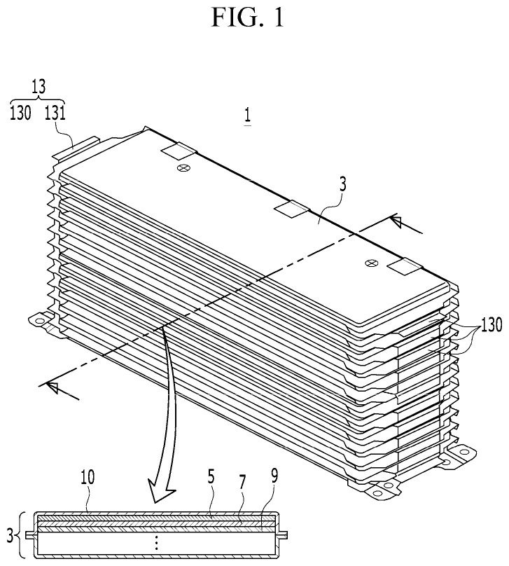

FIG. 1 is a configuration view of a secondary battery to which an electrode manufactured by a method and system for manufacturing an electrode according to the embodiment of the present disclosure is applied.

Referring to FIG. 1, a secondary battery 1 is configured by stacking multiple sheets of electrode assemblies 3 packaged in a pouch 10. The electrode assembly 3 is configured by sequentially stacking a negative electrode 5, a separator 7, and a positive electrode 9.

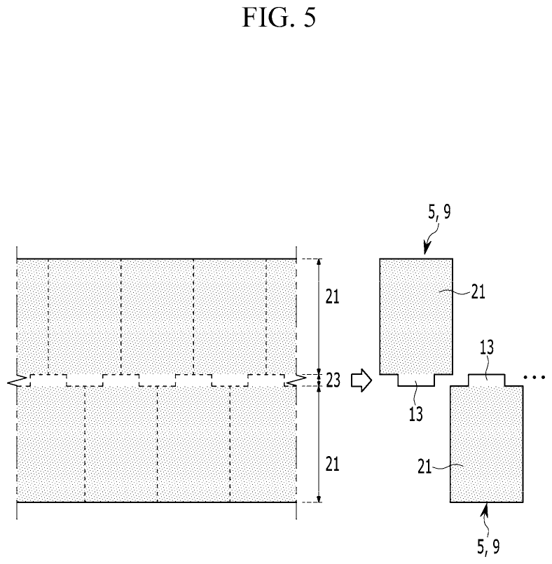

The negative electrode 5 or the positive electrode 9, which constitutes the electrode assembly 3, includes a coated portion 21 having foil 20 coated with a negative or positive electrode active material (hereinafter, the negative electrode active material and the positive electrode active material are referred to as an ‘electrode active material 25’), and an electrode tab 13 protruding from the coated portion 21 (see FIG. 5).

The foil 20 may include any one of copper (Cu) foil 20 and aluminum (Al) foil 20.

The electrode tab 130 of the negative electrode and the electrode tab 131 of the positive electrode are disposed at two opposite sides of the electrode assembly 3 based on a longitudinal direction of the electrode assembly 3.

The electrode tabs 13 are superimposed in the same direction at the time of stacking the electrode assemblies 3.

The method of manufacturing an electrode according to the embodiment of the present disclosure may be applied to manufacture the negative electrode 5 or the positive electrode 9 including the coated portion 21 coated with the electrode active material 25, and the electrode tab 13 protruding from the coated portion 21.

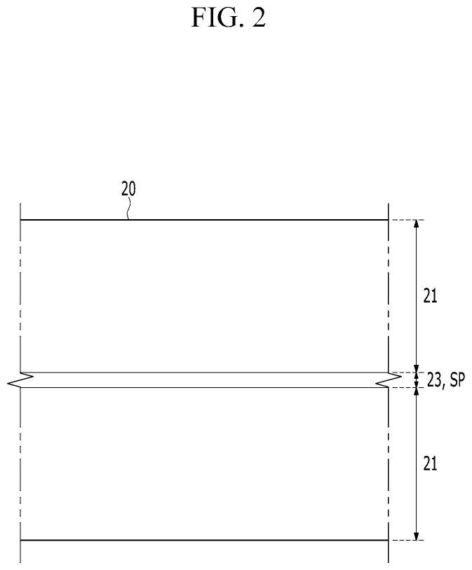

FIGS. 2 to 5 are process diagrams sequentially illustrating the method of manufacturing an electrode according to the embodiment of the present disclosure.

Referring to FIG. 2, the method of manufacturing an electrode according to the embodiment of the present disclosure includes a first step of setting a region SP of the non-coated portion at a center of the foil 20 based on the longitudinal direction.

In the first step, the region SP of the non-coated portion may be set to correspond to a protruding length of the electrode tab 13.

Therefore, the region SP of the non-coated portion may be set depending on the specifications of the secondary battery.

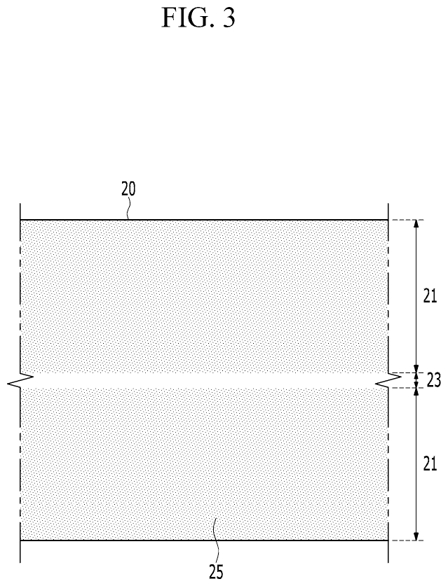

Referring to FIG. 3, in a second step, the electrode active material 25 is applied to two opposite sides of the non-coated portion 23, such that a pair of coated portions 21 is symmetrically formed at the two opposite sides based on the non-coated portion 23.

In the second step, the foil 20 may be coated with the electrode active material 25.

The electrode active material 25 may be any one of the positive electrode active material and the negative electrode active material.

Next, the foil 20 is dried.

The drying process may be performed by allowing the foil 20 to pass through a drying furnace having a long length.

In addition, in the second step, the foil 20 may be rolled by rolling rollers after the foil 20 is coated with the electrode active material 25.

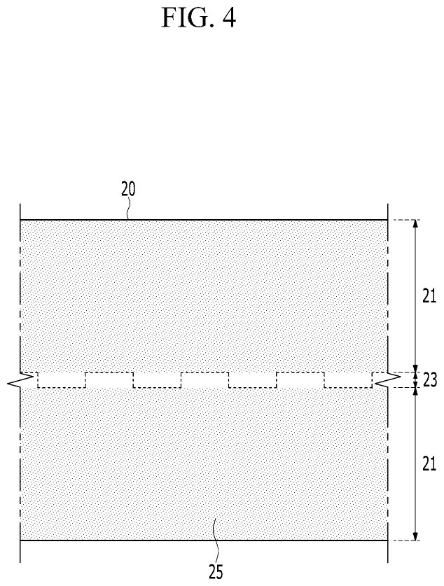

Referring to FIG. 4, in a third step, the non-coated portion 23 is processed to become the electrode tabs 13 with a preset pattern by a cutting unit 50.

In the third step, the cutting unit 50 may form the electrode tabs 13 by patterning the non-coated portion 23 while regularly moving along boundaries between the pair of coated portions 21 and the non-coated portion 23.

For example, in the third step, the non-coated portion 23 may be patterned by being irradiated with laser beams LB.

Referring to FIG. 5, after the third step, a fourth step may be performed to cut the pair of coated portions 21 into pieces each having the single electrode tab 13 and a predetermined size, such that the negative electrode 5 or the positive electrode 9 is formed.

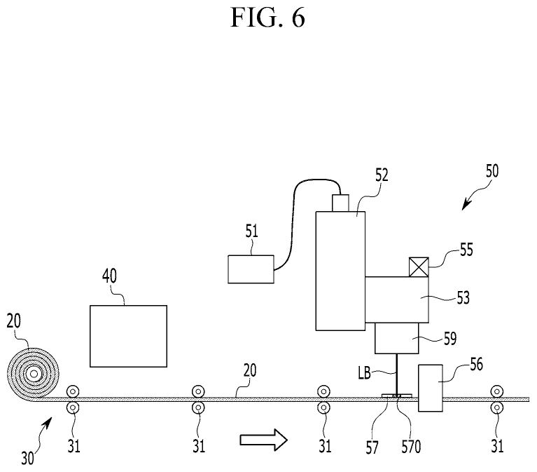

FIG. 6 is a configuration view illustrating a system for manufacturing an electrode according to the embodiment of the present disclosure.

Referring to FIG. 6, the system for manufacturing an electrode, which is applied to the method of manufacturing an electrode, includes a conveying unit 30, a coating unit 40, and the cutting unit 50.

The conveying unit 30 may convey the foil 20 in one direction while unwinding the wound foil 20. For example, the conveying unit 30 may adopt a roll-to-roll technology. That is, the conveying unit 30 may include rollers 31 disposed at predetermined intervals to move the foil 20. Alternatively, the conveying unit 30 may include a conveyor belt.

The coating unit 40 is disposed above the conveying unit 30 and provided at a front side based on the conveyance direction of the foil 20. The coating unit 40 may form the pair of coated portions 21 and the non-coated portion 23 between the pair of coated portions 21 by coating the foil 20 with the electrode active material 25. In general, the coating unit 40 may adopt a method of applying a liquid.

The cutting unit 50 may form the electrode tabs 13 by patterning the non-coated portion 23. The cutting unit 50 includes a laser generator 51, an optical box 52, a scanner 53, a focal point lens 54, a controller 55, a dust collecting part 56, and a guide part 57.

The laser generator 51 emits the laser beams LB. The laser beam LB may have a spot size that does not affect a dimension of the foil 20 at the time of patterning the foil 20.

The optical box 52 is connected to the laser generator 51 and transmits the laser beam LB emitted from the laser generator 51.

The scanner 53 emits the laser beam LB to the non-coated portion 23. The scanner 53 may be attached to an outer portion of the optical box 52.

The focal point lens 54 focuses the laser beam LB scanned by the scanner 53 onto the non-coated portion 23. The focal point lens 54 may be attached to a lower portion of the scanner 53.

Further, the controller 55 moves the scanner 53 in a preset pattern. The controller 55 is connected to the scanner 53 and transmits an inputted preset pattern signal to the scanner 53.

The dust collecting part 56 serves to collect dust produced at the time of patterning the non-coated portion 23 by emitting the laser beam LB to the non-coated portion 23. The dust collecting part 56 may be disposed at a position adjacent to the non-coated portion 23 to which the laser beam LB is emitted.

The guide part 57 fixes the foil 20 to prevent a movement of the foil 20. That is, the guide part 57 pushes the foil 20 in a direction in which the laser beam LB is emitted. The guide part 57 is disposed below the focal point lens 54 in a vertical direction and moves together with the scanner 53.

Further, a through-hole 570 may be formed in the guide part 57 so that the laser beam LB passes through the through-hole 570 and reaches the non-coated portion 23. The guide part 57 may ensure process stability by inhibiting vibration of the foil 20.

The cutting unit 50 may be configured to emit the laser beam LB while the scanner 53 is regularly moved along the boundaries between the pair of coated portions 21 and the non-coated portion 23 by the controller 55.

In this case, the dust collecting part 56 and the guide part 57 are configured to move together with the scanner 53.

Therefore, since the method and system for manufacturing an electrode according to the embodiment of the present disclosure may use the non-coated portion 23 formed between the pair of coated portions 21, thereby minimizing the region of the non-coated portion 23 and reducing costs.

In addition, since the method and system for manufacturing an electrode according to the embodiment of the present disclosure may simultaneously perform the existing cutting and notching processes, thereby minimizing the number of processes and reducing facility costs.

As a result, it is possible to reduce factory investment costs and management costs and improve the operation rate of the facility.

While the present disclosure has been described above with reference to the exemplary embodiments, it may be understood by those skilled in the art that the present disclosure may be variously modified and changed without departing from the spirit and scope of the present disclosure disclosed in the claims.

1: A method of manufacturing an electrode, wherein the electrode comprises a coated portion coated with an electrode active material and an electrode tab protruding from the coated portion, the method comprising:
setting a region of a non-coated portion of the electrode at a center of foil in a longitudinal direction of the foil so the region of the non-coated portion corresponds to a protruding length of the electrode tab;
forming a pair of coated portions at two opposite sides of the non-coated portion by applying the electrode active material so the pair of coated portions is symmetrically disposed at the two opposite sides of the non-coated portion; and
forming the electrode tab with a preset pattern by processing the non-coated portion using a cutting unit.

2: The method of claim 1, wherein the foil is coated with any one of the positive electrode active material and the negative electrode active material.

3: The method of claim 2, wherein forming the pair of coated portions further comprises drying the foil after the foil is coated with the positive electrode active material or the negative electrode active material.

4: The method of claim 3, further comprising after forming the pair of coated portions, rolling the foil using rolling rollers.

5: The method of claim 1, wherein forming the electrode tab comprises patterning the non-coated portion while the cutting unit regularly moves along the boundaries between the pair of coated portions and the non-coated portion.

6: The method of claim 5, wherein forming the electrode tab comprises patterning the non-coated portion by emitting a laser beam.

7: The method of claim 1, further comprising:
after forming the electrode tab, forming a negative electrode or a positive electrode by cutting the pair of coated portions into pieces, each having a predetermined size and comprising the single electrode tab.

8: A system for manufacturing an electrode, wherein the electrode comprises a coated portion coated with an electrode active material and an electrode tab protruding from the coated portion, the system comprising:
a conveying unit configured to convey foil in one direction while unwinding wound foil;
a coating unit disposed above the conveying unit, and provided at a front side in a conveyance direction of the foil, the coating unit being configured to form a pair of coated portions and a non-coated portion between the pair of coated portions by coating the foil with the electrode active material; and
a cutting unit disposed rearward of the coating unit in the conveyance direction of the foil, the cutting unit being configured to process the electrode tab by patterning the non-coated portion.

9: The system of claim 8, wherein the cutting unit comprises:
a laser generator configured to emit a laser beam;
an optical box configured to transmit the laser beam emitted from the laser generator;
a scanner configured to irradiate the non-coated portion with the laser beam;
a focal point lens configured to focus the laser beam scanned by the scanner onto the non-coated portion; and
a controller configured to move the scanner to a preset pattern.

10: The system of claim 9, wherein the cutting unit is configured such that the scanner emits the laser beam while being regularly moved along boundaries between the pair of coated portions and the non-coated portion by the controller.

11: The system of claim 10, wherein the cutting unit further comprises a dust collecting part configured to collect dust produced at the time of patterning the non-coated portion by emitting the laser beam to the non-coated portion.

12: The system of claim 9, wherein the cutting unit further comprises a guide part configured to fix the foil to prevent a movement of the foil.

13: The system of claim 12, wherein the guide part is disposed below the focal point lens in a vertical direction, moves together with the scanner, and has a through-hole through which the laser beam passes to reach the non-coated portion.
